(19) United States
(12) Patent Application Publication
(10) Pub. No.: US 2009/0278762 A1
(43) Pub. Date: Nov. 12, 2009

(54) Antenna Modular Sub-array Super Component

(75) Inventors: Noel Lopez, Phoenix, AZ (US); George A. Hamilton, Peoria, AZ (US); John Filreis, Mesa, AZ (US); Dave Laidig, Mesa, AZ (US)

Correspondence Address: Snell & Wilmer L.L.P (USM/Viasat), One Arizona Center, 400 East Van Buren Street, Phoenix, AZ, 85004-2202, US

(73) Assignee: VIASAT, INC., Carlsbad, CA (US)

(21) Appl. No.: 12/274,994

(22) Filed: Nov. 20, 2008

Related U.S. Application Data
(60) Provisional application No. 61/127,071, filed on May 9, 2008.

(51) Int. Cl. H01Q 1/12; H01Q 1/50; H01R 43/00; H05K 3/34

(52) U.S. Cl. 343/906; 343/908; 29/884; 29/840

(57) ABSTRACT

In accordance with various aspects of the present invention, a method and system for an antenna modular sub-array super component is presented. The modular sub-array super component allows for multiple antenna product designs to utilize a common low cost aperture element assembly block, quantities of which may be scaled up or down to suit the physical, performance, and power requirements of a specific antenna system. More specifically, a method and system for connecting various components of an antenna modular sub-array using a bar with leads connector is discussed. The bar with leads may connect antenna subcomponents or subassemblies.

### RELATED APPLICATION

This application claims priority to U.S. Provisional Application No. 61/127,071, filed May 9, 2008, which is hereby incorporated by reference.

### FIELD OF INVENTION

The present invention relates to an antenna modular sub-array super component. More particularly, the invention relates to the connection of a radiating element interface.

### BACKGROUND OF THE INVENTION

Low profile antennas for communication on the move (COTM) are used in numerous commercial and military applications, such as automobiles, trains and airplanes. Mobile terminals typically require the use of automatic tracking antennas that are able to steer the beam in azimuth and elevation and control polarization in order to follow the satellite position while the vehicle is in motion. Moreover, the antenna should be “low-profile”, small and lightweight, thereby fulfilling the stringent aerodynamic and mass constraints encountered in the typical mounting of antennas in airborne and automotive environments.

Typical approaches for beam steering are: full mechanical scan or full electronic scan. The main disadvantages of the first approach for mobile terminals is the bulkiness of the structure (size and weight of mechanical parts), the reduced reliability (mechanical moving parts are more subject to wear and tear than electronic components), slow tracking, and high assembling costs (less suitable for mass production). The main drawback of fully electronic steering is that the antenna may require at least one Radio Frequency (RF) shifter per radiating element, which may prohibitively raise the cost for commercial applications.

An advantageous approach is to use a “hybrid” steerable beam antenna, i.e. mechanical rotation in azimuth and electronic scanning in elevation. This approach requires only a simple single axis mechanical rotation and a reduced number of electronic components. These characteristics allow for maintaining a low production cost (reduced mechanical parts and electronic components), a reduction in the size and the “height” of the antenna which is important in airborne and automotive applications, and having a better reliability factor than a fully mechanical approach due to fewer mechanical parts.

In addition, to increase performance between 20 degrees and 70 degrees of elevation, the radiating elements may be mounted at an incline. For most satellite communication applications, 20 degrees to 70 degrees of elevation is desired to maintain a link between the antenna and satellite.

Typically, positioning radiating elements at an incline involves multiple fasteners, radio frequency/microwave connectors, and complex assemblies. Each of these fasteners and assemblies typically involve manual installation. Thus, there is a need for a system and method of high manufacturability of radiating elements of an antenna. The invention addresses this and other needs.

### SUMMARY OF THE INVENTION

In accordance with various aspects of the present invention, a method and system for an antenna modular sub-array super component is presented. The modular sub-array super component allows for multiple antenna product designs to utilize a common low cost aperture element assembly block, quantities of which may be scaled up or down to suit the physical, performance, and power requirements of a specific antenna system. More specifically, a method and system for connecting various components of an antenna modular sub-array using a bar with leads connector is discussed. The bar with leads may connect antenna subcomponents or subassemblies.

Furthermore, in an exemplary embodiment, leads are angled or bent. In one embodiment, the leads of the bar with leads connector are bent to a desired angle to allow connection of an inclined surface and another surface, for example, an inclined antenna module. In another exemplary embodiment, a first end of a lead is in one plane and a second end of the lead in is a different plane. In an exemplary embodiment, the leads are bent at an angle in the range of 30 to 60 degrees between the first end and the second end of the lead.

In another exemplary embodiment, a bar with leads connector includes a substantially flat bar with at least one lead attached. The lead is bent within the length of the lead and is configured to attach to a lead pad. Additionally, the bar is designed to disconnect from the bar with leads connector, leaving the lead connected to the lead pad.

### BRIEF DESCRIPTION OF THE DRAWING FIGURES

A more complete understanding of the present invention may be derived by referring to the detailed description and claims when considered in connection with the drawing figures, wherein like reference numbers refer to similar elements throughout the drawing figures, and:

FIG. 1 shows an exploded view of a prior art example of an antenna module with a coaxial RF connector;

FIG. 2 shows two examples of a bar with leads connector;

FIG. 3 shows an example graph depicting insertion loss;

FIG. 4 shows an exemplary graph depicting return loss;

FIG. 5 shows two examples of a printed circuit board;

FIG. 6 shows two examples of a bar with leads connector before attachment and two circuit boards with leads attached;

FIG. 7 shows a flowchart of a method for attaching multiple leads to a PCB using a bar with leads connector;

FIG. 8 shows three examples of support brackets, including an example of a support bracket with an exemplary pick-up tab;

FIG. 9 shows an example of multiple antenna modules;

FIG. 10 shows an example of an antenna module;

FIG. 11 shows two examples of a circuit board panel;

FIG. 12 shows a side view of a hybrid phased array antenna constructed with super components partially assembled;

FIG. 13 shows an exploded view of an example of an antenna aperture;

FIG. 14 shows a perspective view of a close-up example of an antenna module with a leads connection to a steering printed circuit board;

FIGS. 15A, 15B shows perspective views of an exemplary RF lead interface;

FIG. 16 shows a perspective view of an example of an antenna assembly; and

FIG. 17 shows a flow chart of an example of a manufacturing process flow.

### DETAILED DESCRIPTION

While exemplary embodiments are described herein in sufficient detail to enable those skilled in the art to practice the invention, it should be understood that other embodiments may be realized and that logical electrical and mechanical changes may be made without departing from the spirit and scope of the invention. Thus, the following detailed description is presented for purposes of illustration only.

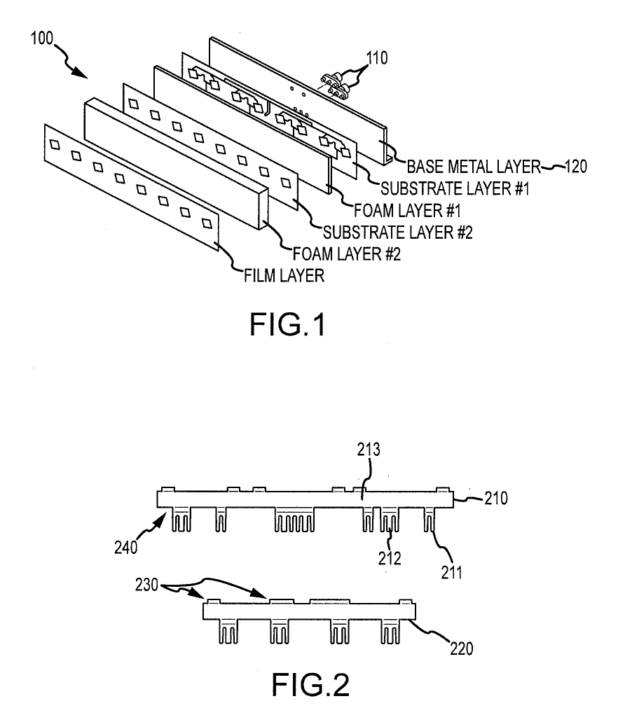

With reference to FIG. 1, a prior art antenna module 100 includes a coaxial radio frequency (RF) connector 110 and a base metal layer 120. Some examples of a common coaxial RF connector 110 used in prior art systems include an SMA (subminiature version A) connector, a Molex SSMCX, and a Huber Suhner MMBX. The use of such connections result in a complex assembly because the connectors must be hand-tightened and there are a large number of connectors in a prior art antenna using module 100. The connections also may result in an overall taller antenna module due to the size of the connectors and space needed to install them.

In accordance with an exemplary embodiment of the present invention, and with reference to FIG. 2, various exemplary bar with leads connectors are discussed. A bar with leads connector may also be described as a lead frame. For example, bar with leads connector 210, 220 may comprise a bar 213 and two or more leads 211, 212. Furthermore, bar with leads connector 210, 220 may include a break-away point 240 which is, for example, a point that is scored or etched to provide a suitable point of separation of the bar from the leads.

In an exemplary embodiment, bar 213 is flat and configured to provide a flat area for vacuum pick-up implemented by typical pick-and-place machines. Apart from providing a suitable flat area for the pick and place machine, in another embodiment, the bar may be configured to shift the center gravity of the bar with leads connector 210, 220 to the flat area. In order to provide a stable place to pick up the bar with leads connector, the bar with leads connector may be designed, for example, so that the center of gravity is not over the leads or edge.

In another embodiment, bar 213 also has feet 230, allowing for bar with leads connector 210, 220 to be installed during assembly over other previously installed components. In other words, electrical components and/or printed circuit lines may be present on a printed circuit board (PCB) when bar with leads connector 210, 220 is attached. In an exemplary embodiment, bar 213 angles up from the PCB, creating space between bar 213 and the PCB. In the exemplary embodiment, feet 230 extend from bar 213 and provide structural support for the space between bar 213 and the PCB. By providing spacing using feet 230, the bar with leads does not interfere, and possibly damage, the other components on the PCB.

Furthermore, there are many types of leads. Leads 211 may, for example, be direct current lead connections. Leads 212 may, in another example, be RF lead connections. In an exemplary embodiment, the RF lead connections comprise a ground-signal-ground design of leads. In accordance with an exemplary embodiment, bar with leads connector 210, 220 may be configured for use on transmit or receive antennas. Thus, for example, bar with leads connector 210 may be configured to attach to a printed circuit board for a receive antenna. In another example, bar with leads connector 220 may be configured to attach to a printed circuit board for a transmit antenna. Furthermore, in an exemplary embodiment, bar with leads connector 210, 220 is configured to attach to a printed circuit board for a transceiver antenna.

In an exemplary embodiment, bar with leads connector 210, 220 is designed with specific spacing of leads 211, 212 such that the leads align with lead pads on the surfaces to which the leads are attached. Additionally, in an exemplary embodiment, bar with leads connector 210, 220 may be any structure that holds two or more leads for attachment to other structures.

Furthermore, in an exemplary embodiment, leads 211, 212 are angled or bent. In one embodiment, the leads of bar with leads connector 210, 220 are bent to a desired angle to allow connection of an inclined surface and another surface. The inclined surface, for example, is an antenna module and the other is a mounting surface. In another exemplary embodiment, a lead comprises a first end and a second end. The first end of the lead is in one plane and the second end of the lead in is a different plane. In an exemplary embodiment, the leads are bent at an angle in the range of 2 to 90 degrees between the first end and the second end of the lead. In another exemplary embodiment, the leads are bent at any suitable angle for connecting two surfaces as would be known to one skilled in the art. Also, the lead may be bent at any point along the lead, for example it may be bent in the middle or along a third of the lead length.

In one embodiment, bar with leads connector 210, 220 is made of copper. In another embodiment, bar with leads connector 210, 220 may be made of at least one of BeCu and steel. In yet another embodiment, the leads are plated with materials that are conducive to soldering, such as, for example, tin, silver, gold, or nickel. Moreover, bar with leads connector 210, 220 may be made of, or plated with, any suitable material as would be known to one skilled in the art.

Additionally, in an exemplary embodiment, RF lead connections provide a connection with a broad bandwidth and a low loss. In an exemplary embodiment, broad bandwidth is bandwidth with a range of DC to 15 GHz. In another embodiment, broad bandwidth is bandwidth with a range of DC to 80 GHz or any suitable range in between. Furthermore, in an exemplary embodiment, low loss is loss in the range of 0.01 dB to 1.5 dB as the loss is a function of frequency. Additionally, there may be other suitable ranges of low loss as is known in the art. The RF leads may provide such a connection for at least one of the X band, the Ku band, the K band, the Ka band, and the Q band. Moreover, the RF may provide such a connection for other suitable bands as would be known to one skilled in the art.

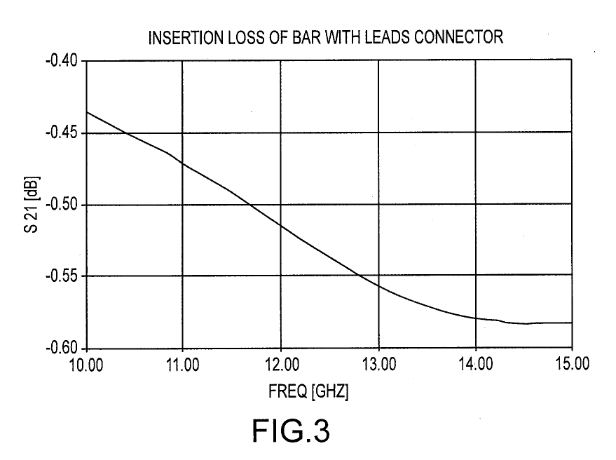

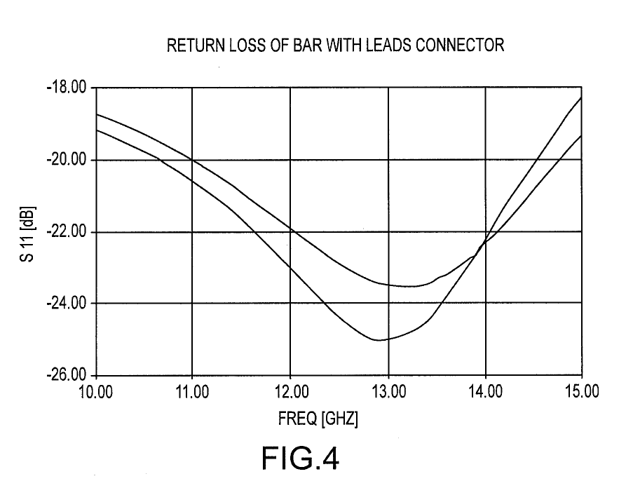

In addition, in an exemplary embodiment and with reference to FIG. 3, the RF lead connections provide a low pass response, e.g., filtering. In an exemplary embodiment, the insertion loss is less than 0.6 dB up to about 15 GHz. Furthermore, in an exemplary embodiment and with reference to FIG. 4, the return loss of the interface is more than about 18 dB up to 15 GHz and better than about 20 dB for the range of 11-14.5 GHz.

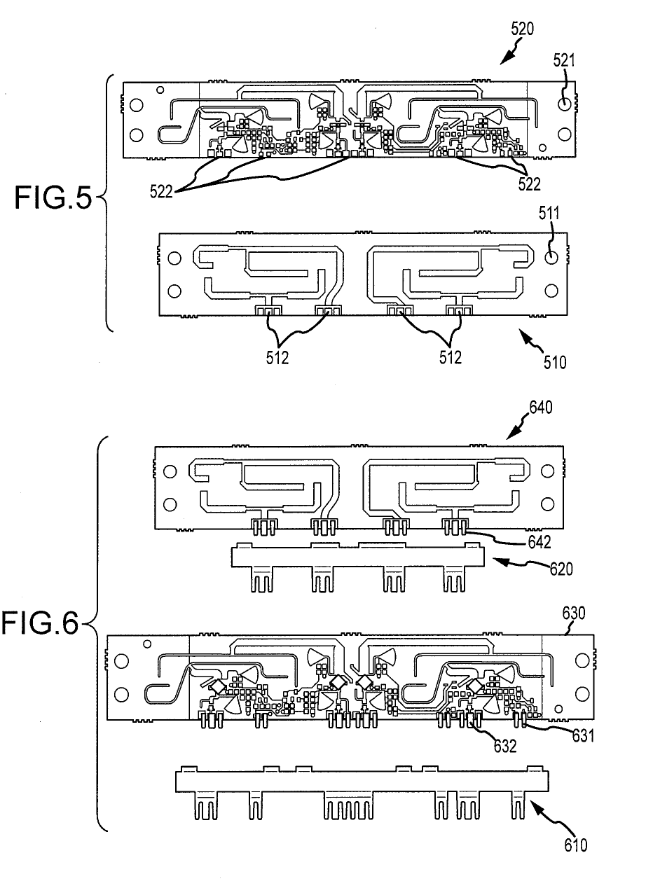

In an exemplary embodiment, and with reference to FIG. 5, various printed circuit boards (PCB) are discussed. In one embodiment, a PCB 510, 520 comprises tooling holes 511, 521 and lead pads 512, 522. Tooling holes may align PCB 510, 520 to help test or assemble fixtures. Tooling holes may also align PCB 510, 520 to other sub-assemblies or components. Furthermore, in an exemplary embodiment, PCB 510 is a transmit PCB and PCB 520 is a receive PCB. As a transmit PCB, PCB 510 may comprise matching structures and bias feeds. As a receive PCB, PCB 520 may further comprise at least one resistor, at least one capacitor, and/or a low noise amplifier (LNA) transistor(s). In general, PCB 510, 520 may be any laminate or substrate that carries signals and holds components.

In an exemplary embodiment, and with reference to FIG. 6, an exemplary PCB 630 comprises leads 631, 632. Leads 631, 632 are attached using a bar with leads such as bar with leads connector 610. Another exemplary PCB 640 comprises leads 642. The leads 642 were attached using a bar with leads, such as bar with leads connector 620. In an exemplary embodiment, lead 631 is a direct current lead. In another exemplary embodiment, leads 632, 642 are RF leads.

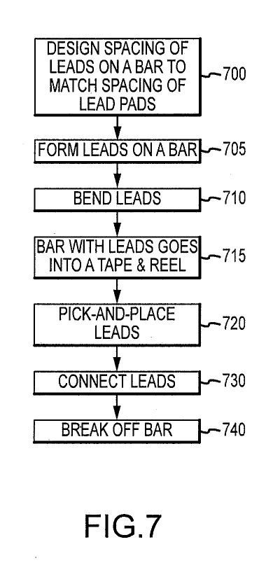

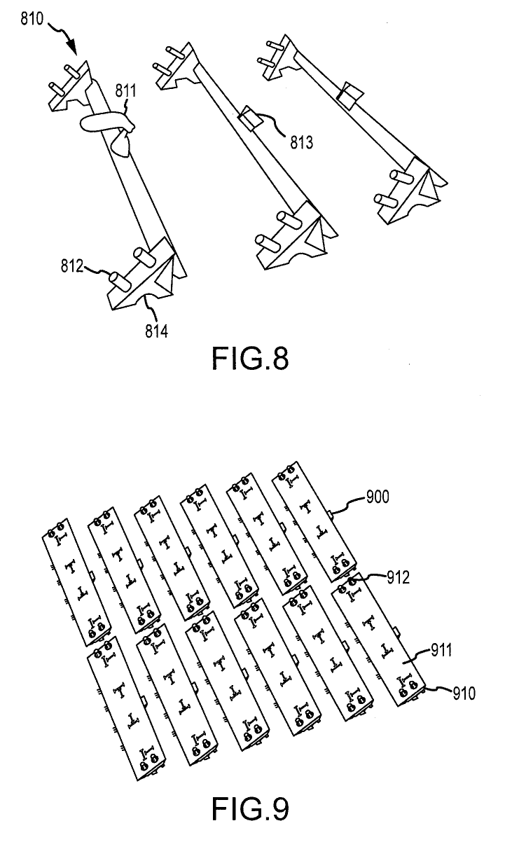

In accordance with an exemplary method, and with reference to FIG. 7, a bar with leads connector is attached to a PCB. The exemplary method may comprise designing the spacing of leads of the bar with leads connector such that the spacing of the leads matches the spacing of lead pads on the PCB (Step 700). In accordance with various exemplary embodiments, leads and feet are cut, etched, and/or formed on a bar (Step 705). The leads may be of any suitable length and spaced apart as desired. The leads of the bar with leads connector are bent to a desired angle (step 710). In another exemplary embodiment, the feet may be formed in the same step. The bend of the leads may be configured to allow connection of an antenna module to another surface where the antenna module is inclined relative to the other surface. In an exemplary embodiment, the leads are bent at an angle in the range of 2 to 90 degrees from the bar. In an exemplary embodiment, leads may be bent, formed, or stamped to the desired angle by a machine. In another exemplary embodiment, the bar with leads may then be installed into a tape and reel (Step 715). The tape and reel provides another manner of machine handling the bar with leads to feed a pick-and-place machine. Then the bar with leads connector is placed into correct position on the PCB such that the leads are aligned with corresponding lead pads (Step 720). This placement may be done, for example, by a machine in a pick-and-place manner. An exemplary method may comprise any combination of the described steps.

In an exemplary embodiment, a machine picks and places the bar with leads by suction or a gripping mechanism, using the flat surface of the bar with leads connector. Once the bar with leads connector is correctly positioned, the leads are connected to the PCB (Step 730), which may occur through various known techniques. In an exemplary embodiment, bar with leads connector 610 is attached to PCB 630 through reflow solder technique. The specifics of reflow solder technique are known and may not be discussed herein. In another embodiment, the leads of the bar with leads connector are attached to the PCB by an epoxy attachment or through any other suitable method now known or hereinafter devised. For example, a machine may dispense conductive epoxy on the PCB pads prior to placement of the bar with leads connector. In this example, the epoxy cures to attach the leads to the PCB. After the bar with leads connector is connected to the PCB, the bar portion of the bar with leads connector is broken off (Step 740), leaving just the leads attached to the PCB. The bar may be broken off or detached either manually or with a machine, using any bending, snapping, cutting, laser or other suitable method.

With reference now to FIG. 8, an exemplary support bracket 810 is described. In one embodiment, support bracket 810 comprises a pick-up tab 811. In another embodiment, support bracket 810 further comprises tooling pins 812, an alignment tab 813, and alignment pins under feet 814.

In an exemplary embodiment, support bracket 810 is plastic. A plastic support bracket may be molded into a desired shape, and provides a low cost and manufacturability method of supporting the PCB at any angle between 5-90 degrees. Furthermore, support bracket 810 may be made of other light weight materials such as zinc, magnesium, aluminum, and/or ceramic. Moreover, support bracket 810 may comprise any other suitable material as would be known to one skilled in the art.

In an exemplary embodiment, support bracket 810 defines the angle of a radiating element in an antenna aperture. In one embodiment, support bracket 810 is configured to support a radiating element at an angle in the range of 30-60 degrees. In another embodiment, support bracket 810 is configured to support a radiating element at an angle of about 45 degrees. Moreover, support bracket 810 may be configured to support a radiating element at any angle suitable for optimal performance of an antenna.

Pick-up tab 811 may be used to move support bracket 810. For example, a machine may clutch or suction onto pick-up tab 811 in order to place support bracket 810 into a desired location. This may be accomplished, for example, by a pick-and-place machine. Moreover, additional techniques to move support bracket 810 are contemplated as would be known to one skilled in the art.

In one embodiment, tooling pins 812 are configured to align with holes in various antenna module components, such as a PCB. Tooling pins 812 hold and stack the various antenna module components in place. In one embodiment, an antenna module is machine assembled for attaching a support bracket and the PCB to a steering card prior to attaching a foam radiating element to the support bracket. This is due in part to the heat from reflow soldering of components which might otherwise result in potential damage to a foam component. In another exemplary embodiment, the components of an antenna module may be assembled in any suitable order. This may involve hand assembly and/or the use of heat in such a manner as to not result in any substantial impact on any component.

Furthermore, in an exemplary embodiment, alignment pins under feet 814 are protruding shapes along the bottom of support bracket 810. In another embodiment, alignment pins under feet 814 are metal plated or at least have metal deposits on the bottom of the feet. Alignment pins under feet 814 may assist in guiding support bracket 810 into a correct placement on another surface when, for example, the other surface comprises matching concave areas or placement holes. The alignment pins under feet 814 may be configured to provide additional structural support required in COTM applications. When alignment pins under feet 814 are metal plated, support bracket 810 may become a surface mount component similar to other surface mount components. Furthermore, in an exemplary embodiment, support bracket 810 is self-aligning. When the super component subarray is designed to be light weight, the surface tension of the solder during surface mount reflow may facilitate centering the sub-array super component on the PCB mounting pads. This provides very accurate positioning of the sub-array super component on the steering card. Accurate positioning of the sub-array components helps to facilitate the optimal performance of the antenna.

In accordance with an exemplary embodiment, and with reference to FIG. 9, a partially assembled antenna module 900 may include a support bracket 910 and a PCB 911 connected to support bracket 910 via tooling pins 912.

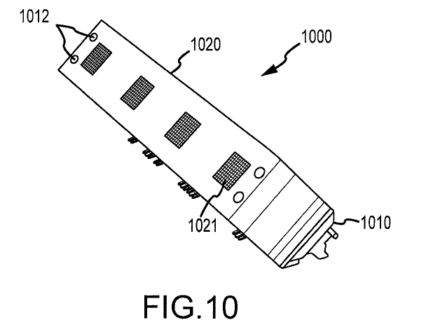

Furthermore, in an exemplary embodiment, and with reference to FIG. 10, an assembled antenna module 1000 may comprise a support bracket 1010, a foam component 1020, and at least one parasitic patch 1021 connected together via tooling pins 1012. In other embodiments, foam component 1020 may be any other low loss laminate with a low loss tangent. In an exemplary embodiment, parasitic patches 1021 form the desired radiation pattern. Furthermore, foam component 1020 includes holes aligned for tooling pins 1012.

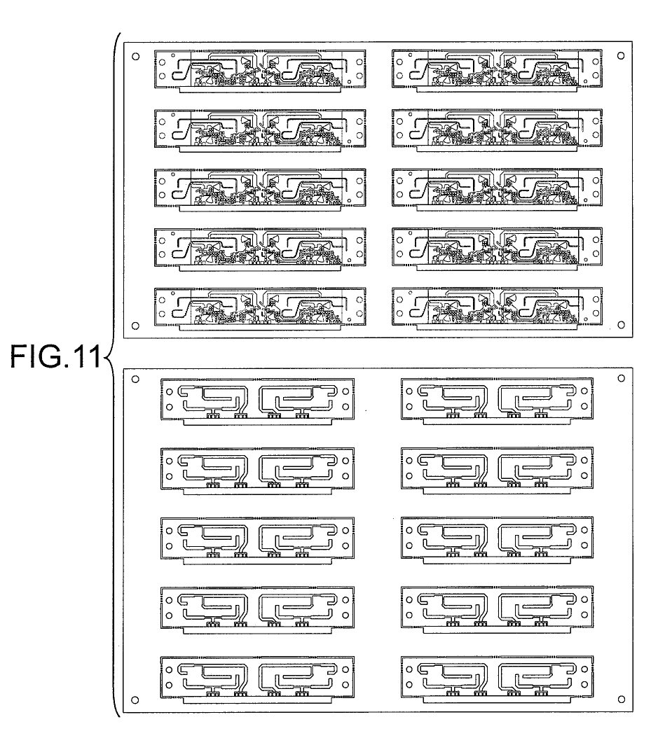

With reference to FIG. 11, an exemplary method of assembly includes manufacturing various components in a panel. In other words, multiple antenna modules may be formed on a single panel. In an exemplary embodiment, a matching structure, ground vias, and/or bias feed are printed onto a circuit board. In addition, other structures may be printed on a circuit board as would be known to one skilled in the art. In one embodiment, the PCBs may be separated from the panel and assembly as an individual PCB. In another embodiment, the PCBs are also fully or partially assembled and tested in panel form when attaching the leads, which may be done by machine or by hand. An exemplary method of attaching the leads to a PCB is further discussed with reference to FIG. 7. Additionally, other discrete components may be attached to the antenna module while in panel form. The individual PCB's may then be separated from the panel, after full or partial assembly of the sub-array super component.

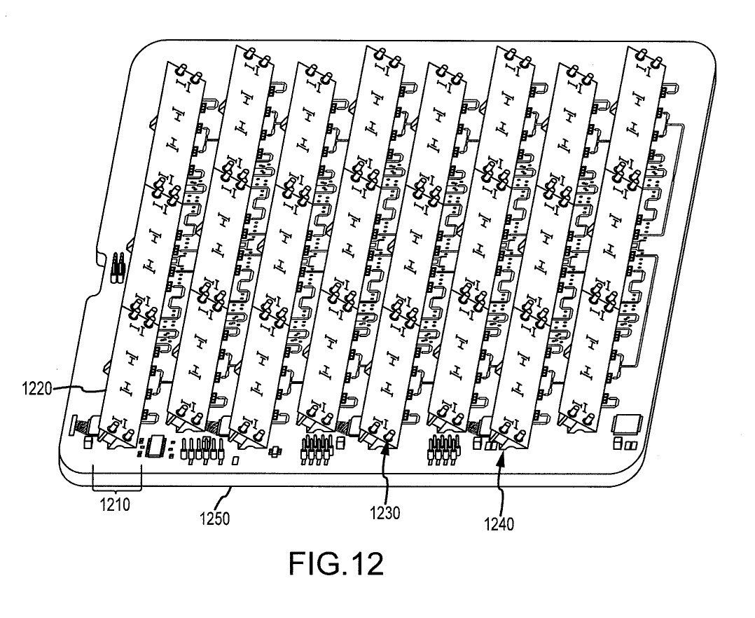

In accordance with an exemplary embodiment, and with reference to FIG. 12, an array of super components 1210 are designed and attached to a mounting plate 1250. In an exemplary embodiment, a super component includes a PCB 1220 connected to a support bracket 1240. PCB 1220 may be connected to support bracket 1240 via tooling pins 1230. In an exemplary embodiment, various scalable designs are assembled from super components without redesigning the sub-array. As shown in FIG. 12, twenty-four super components 1210 are arranged on mounting plate 1250. Other arrangements may be designed using super components as a building block, invoking the benefits of scalable design.

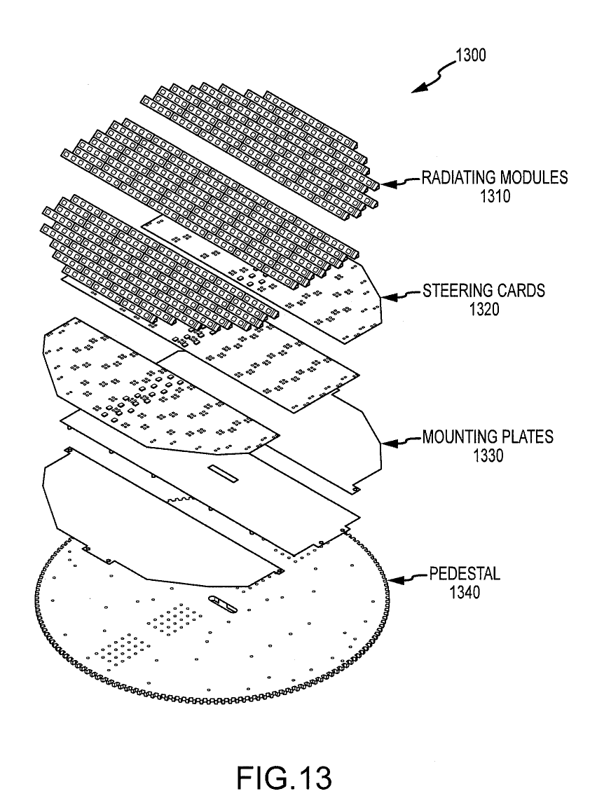

Furthermore, in an exemplary embodiment, and with reference to FIG. 13, an RF antenna aperture 1300 comprises radiating modules 1310, a steering card 1320, a mounting plate 1330, and a pedestal 1340. In one embodiment, aperture 1300 includes steering card 1320 and/or mounting plate 1330 formed by multiple pieces.

An exemplary embodiment of a steering card 1320 includes an elevation beam forming network, an azimuth beam forming network to perform at least part of the azimuth network, and at least one phase shifter. In an exemplary embodiment, the beam forming network components are splitters. Additionally, steering card 1320 may also include an amplifier, such as a power amplifier for a transmit steering card and a low noise amplifier for a receive steering card.

In an exemplary embodiment, RF antenna aperture 1300 further comprises mounting plate 1330. Mounting plate 1330 provides support structure and may also function to dissipate and spread heat from amplifiers. In addition, mounting plate 1330 provides a clean interface to connect (e.g., bolt, fasten, adhere) to pedestal 1340.

In an exemplary embodiment, pedestal 1340 comprises an edge with teeth to match with gears so that pedestal 1340 may be mechanically rotated by a motor. In another embodiment, pedestal 1340 and mounting plate 1330 are integrated into a single piece.

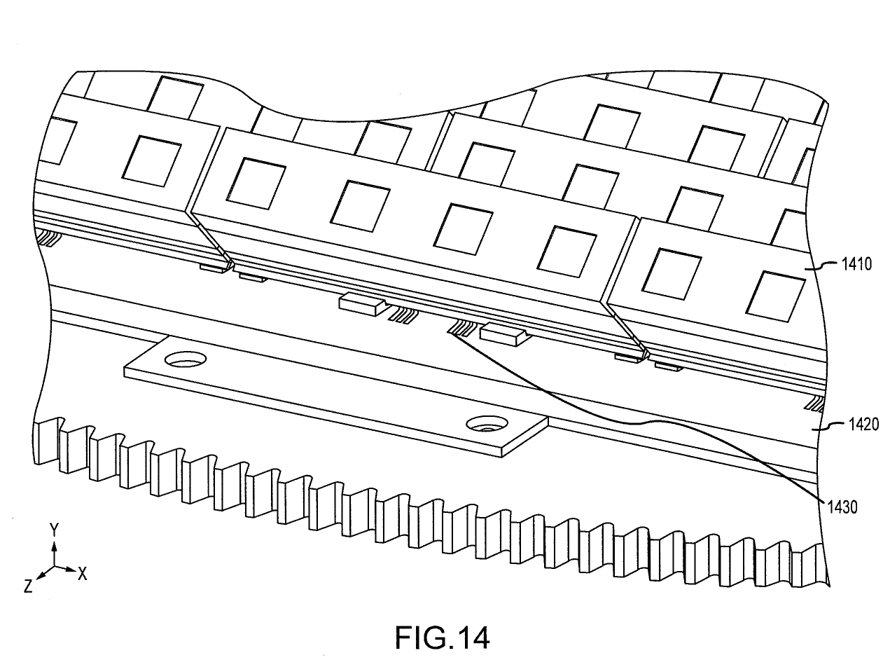

With reference to FIG. 14, a radiating module 1410, such as the exemplary radiating module described with reference to FIG. 10, is connected to a steering card 1420 via leads (1430 typ.). In an exemplary embodiment, lead 1430 is pre-bent to substantially match the angle between the steering card 1420 and the radiating module 1410.

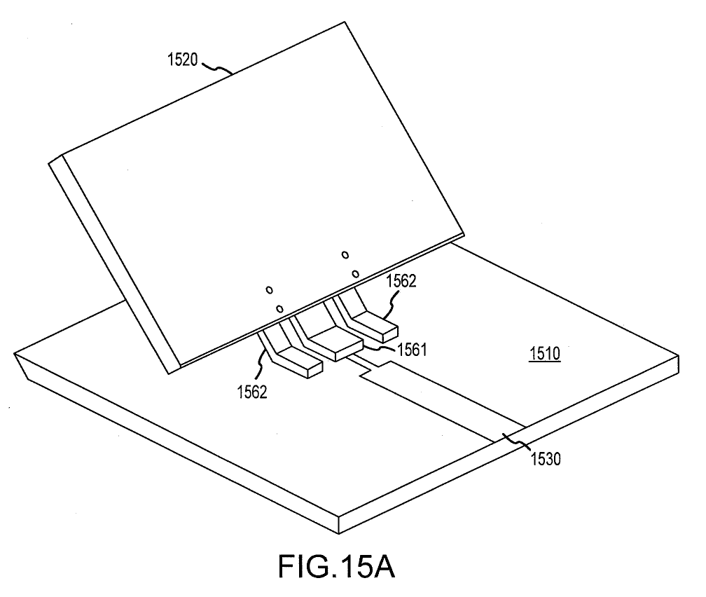

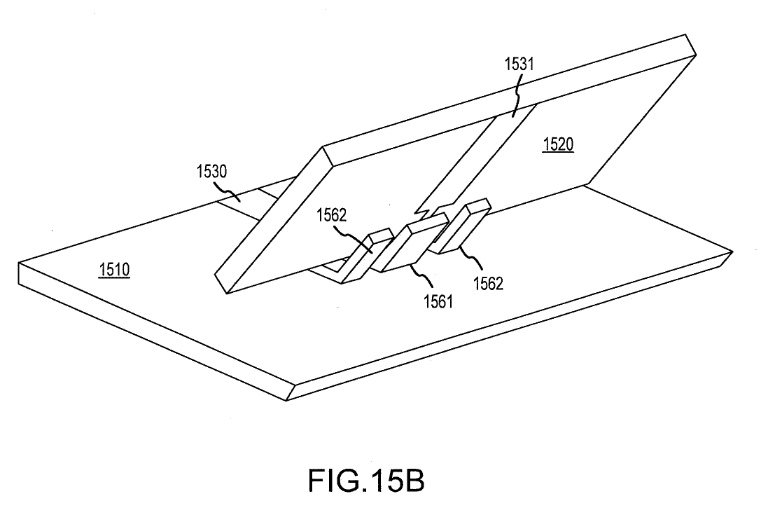

Furthermore, and with reference to FIGS. 15A and 15B, an exemplary interface between a steering card 1510 and a radiating element PCB 1520 is shown. In an exemplary embodiment, a microstrip line 1530 is located on steering card 1510 and connects to one or more lead pads 1540, which in turn connect to a microstrip line 1531 on steering card 1510. In addition, in another embodiment, ground vias (not shown) are located between lead pads (not shown) and steering card 1510. In an exemplary embodiment, the lead pads are underneath and connect to a group of leads, which includes two ground leads 1562 and a signal lead 1561.

In an exemplary embodiment, signal lead 1561 facilitates the transmission of a signal between radiating element PCB 1520 and steering card 1510. In the exemplary embodiment, a first end of signal lead 1561 connects to microstrip line 1530 on steering card 1510, and a second end of signal lead 1561 connects to microstrip line 1531 on radiating element PCB 1520.

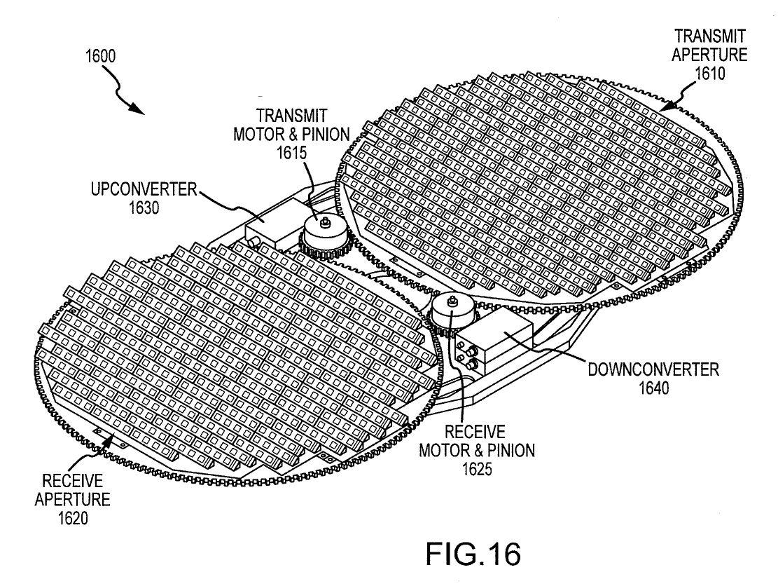

In accordance with an exemplary embodiment and with reference to FIG. 16, a full antenna assembly 1600 includes a transmit aperture 1610, a transmit motor 1615, a receive aperture 1620, a receive motor 1625, an upconvertor 1630, and a downconvertor 1640. Transmit motor 1615 and receive motor 1625 power the rotation in the azimuth plane. Upconvertor 1630 frequency converts an intermediate frequency (IF) signal from a modem up to the transmit RF frequency of the aperture. In addition, downconvertor 1640 frequency converts the receive RF signal from the aperture down to the modem IF frequency.

Furthermore, an antenna module may be connected to another surface in other assemblies, such as an assembly that communicates a signal from one PCB to another. In an exemplary embodiment, the interface connection may be used in U.S. Monolithics products such as the Ka Band XCVR and Link-16 RF modules. Furthermore, the interface connection may be implemented in non-radio frequency applications, for example in communicating a signal from a digital mother board to a daughter card.

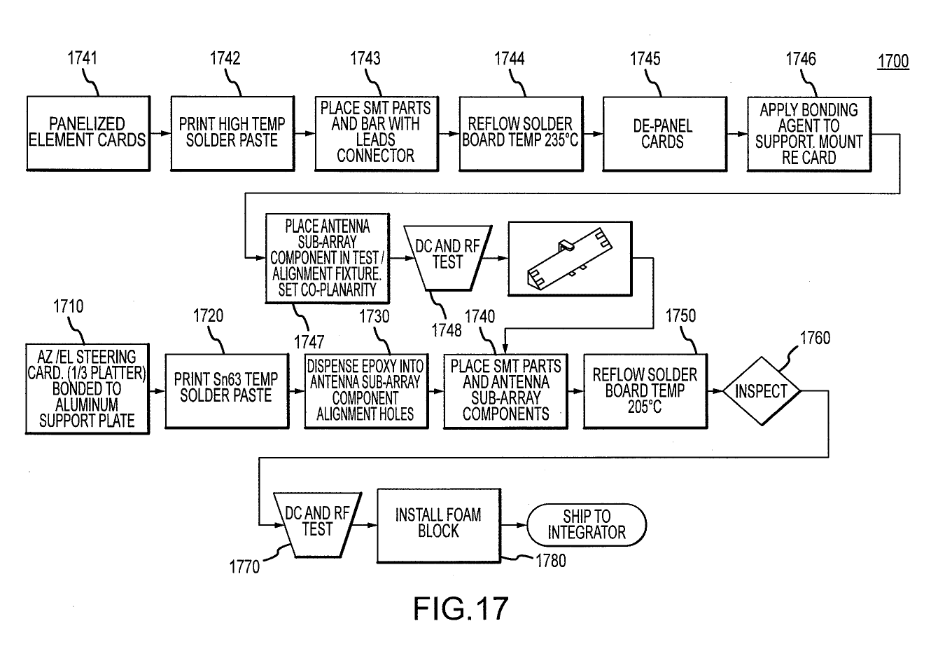

In an exemplary method, and with reference to FIG. 17, a manufacturing method 1700 is described herein. A steering card bonds to a support plate (Step 1710). The support plate ensures the assembly is substantially flat, as well as providing thermal transfer, dissipation and a manner for mechanical attachment to the next higher assembly. Additionally, solder paste is added to the steering card (Step 1720). In an exemplary embodiment, the solder paste has a liquidus temperature of about 183° C., thereby allowing attachment of all placed components while not disturbing the solder used to attach components to the radiating element cards.

Furthermore, another step is dispensing epoxy into antenna sub-array super component alignment holes (Step 1730). In one embodiment, epoxy is added as structural support required by the end use environment. Additionally, one step is the placement of the SMT (surface mount technology) parts and antenna sub-array super components (Step 1740) on the steering card. Furthermore, the SMT parts and antenna sub-array super components are attached to the steering card using reflow soldering (Step 1750), in one embodiment at a board temperature of about 205° C. Additionally, method 1700 may further comprise inspecting the board (Step 1760), functional performance testing (Step 1770), and adding foam bricks to the antenna sub-array super component (Step 1780).

The antenna sub-array super components are assembled using various methods. In one exemplary method of manufacture, the bare element PCBs are created in a panelized form (Step 1741) and high temperature solder paste is printed on the element PCBs (Step 1742). In an exemplary embodiment, the liquidus temperature of this solder formulation is about 217° C. and is selected so that parts attached to the super component circuit boards with high temperature solder paste will remain substantially unaffected by the additional soldering process temperature described in Step 1750, wherein steering card components are solder attached in conjunction with the super component leads at a temperature of about 205° C.

Another step is the placement of SMT parts and bar with leads connector (Step 1743) on the element PCBs. After the placement of SMT parts, reflow soldering occurs (Step 1744), in one embodiment at a board temperature of about 235° C. The PCBs are de-paneled, generally once the SMT parts are attached (Step 1745). Furthermore, an additional step in this embodiment is the application of a bonding agent (Step 1746), and attachment of the support bracket which, working in conjunction with the bar with leads connector, creates the form factor of the radiating element module sub-array super component and allows mounting of a super component PCB. Furthermore, an additional step in this embodiment is placing the super component module in a test/alignment fixture and setting co-planarity of the super component module (Step 1747). This method of assembling an antenna sub-array super component may further comprise testing the leads connection from the PCB to a steering card (Step 1748). Additionally, by machine assembling various components, the antenna sub-array super component modules may be manufactured with a high rate of throughput. This in turn lowers the cost of assembly and the cost of the antenna device.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “includes,” “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Further, no element described herein is required for the practice of the invention unless expressly described as “essential” or “critical.”

What is claimed is:

1. A bar with leads connector comprising:
a substantially flat bar; and
at least one lead connected to the substantially flat bar, wherein the at least one lead comprises a first end in a first plane and a second end in a second plane;
wherein the first plane is not co-planar with the second plane; and
wherein the at least one lead is configured to communicate a signal between an inclined surface and a mounting surface.

2. The bar with leads connector of claim 1, wherein the inclined surface is a printed circuit board of an antenna module.

3. The bar with leads connector of claim 1, wherein a portion of the bar with leads connector is part of an antenna sub-array super component.

4. The bar with leads connector of claim 1, wherein the at least one lead is bent at an angle in the range of 2-90 degrees.

5. The bar with leads connector of claim 1, wherein the at least one lead is configured to provide the signal with a bandwidth connection with a range of DC to 15 GHz.

6. The bar with leads connector of claim 1, wherein the at least one lead is configured to provide the signal with a bandwidth connection with a range of DC to 80 GHz.

7. The bar with leads connector of claim 1, wherein the bar with leads connector is configured to communicate the signal with a loss in the range of 0.01 dB to 1.5 dB.

8. The bar with leads connector of claim 1, wherein the signal is in at least one of the X band, Ku band, K, band, or the Q band.

9. The bar with leads connector of claim 1, further comprising feet configured to provide space between the bar with leads connector and the inclined surface.

10. The bar with leads connector of claim 1, wherein the bar with leads connector is configured to be relocated using a pick-and-place device, and wherein the bar with leads connector is designed such that the center of gravity of the bar with leads connector is within the substantially flat bar in order to facilitate relocation with the pick-and-place device.

11. The bar with leads connector of claim 1, wherein the bar with leads comprises at least one of copper, beryllium copper, or steel; and wherein the at least one lead is plated with at least one of tin, silver, gold, or nickel.

12. A super component assembly, comprising:
a printed circuit board (PCB) with a first side and a second side;
at least one lead connected to the PCB;
a support bracket connected to the first side of the PCB; and
at least one radiating element located on the second side of the PCB.

13. The super component assembly of claim 12, wherein the PCB is inclined at an angle relative to a mounting surface, and wherein the angle of the PCB relative to the mounting surface is in the range of 30-60 degrees.

14. The super component assembly of claim 12, wherein the support bracket further comprises:
a pick-up tab configured to facilitate moving the super component assembly;
tooling pins configured to align the support bracket with the PCB using tooling holes; and
alignment posts under feet configured to facilitate alignment of the support bracket with the mounting surface, wherein the alignment posts under feet of the support bracket are at least one of metal or metal coated.

15. The super component assembly of claim 14, wherein the support bracket is self-aligning with the mounting surface, and wherein the radiating element comprises a foam component and at least one parasitic patch, and wherein the super component assembly does not comprise a cable connection.

16. A method comprising:
forming leads on a bar;
bending the leads to a designed angle;
attaching the leads to a first surface; and
breaking off the bar and leaving the leads attached to the first surface;
wherein the leads are configured to connect to a second surface, and wherein the second surface is at an angle relative to the first surface.

17. The method of claim 16, wherein breaking off the bar uses at least one of manual force, cutting, bending, or a laser.

18. The method of claim 16, further comprising:
designing the spacing of the leads to match lead pads on the first surface;
utilizing a tape and reel; and
moving the bar using a pick and place device.

19. A method of manufacturing a super component, comprising:
panelizing an array of printed circuit boards (PCBs);
printing high temperature solder paste on the array of PCBs;
placing surface-mount technology (SMT) components and at least one bar with leads on the array of PCBs;
reflow soldering the SMT components and the at least one bar with leads;
forming a connection between the SMT components and the least one bar with leads with the array of PCBs.

20. The method of claim 19, further comprising depanelizing the array of PCBs.
